(19) United States
(12) Patent Application Publication
(10) Pub. No.: US 2025/0019293 A1
(43) Pub. Date: Jan. 16, 2025

(54) PATTERNED LOW MELTING GLASS (LMG) PHOTONIC FILM SURFACES BY WET-ETCH PHOTOLITHOGRAPHY

(71) Applicant: CORNING INCORPORATED, CORNING, NY (US)

(72) Inventors: Leonard Charles Dabich, II, Painted Post, NY (US); Traci Nanette Harding, Corning, NY (US); Cameron Robert Nelson, Elmira, NY (US); Mark Alejandro Quesada, Horseheads, NY (US); William Allen Wood, Painted Post, NY (US); Bin Zhu, Ithaca, NY (US)

(21) Appl. No.: 18/706,908

(22) PCT Filed: Oct. 28, 2022
(86) PCT No.: PCT/US2022/048175

§ 371 Date: May 2, 2024

Related U.S. Application Data
(60) Provisional application No. 63/276,717, filed on Nov. 8, 2021.

(51) Int. Cl. C03C 15/00; C03C 3/247; C03C 17/00; G03F 7/16

(52) U.S. Cl. CPC C03C 15/00; C03C 3/247; C03C 17/002; G03F 7/162; G03F 7/168; C03C 2218/151; C03C 2218/154

(57) ABSTRACT

A glass article comprises a film layer deposited on a glass substrate. The film layer has a melting point less than 450° C. and comprises a thickness and a primary surface. The primary surface defines at least one elevated surface protruding relative to the at least one relief surface. The elevated surface forms a periodic pattern defined by an etch mask, and the relief surface is defined as an inverse pattern of the etch mask. The duration of an etching process applied to the film layer defines a ratio of a first area of the elevated surface to a second area of the relief surface.

### CROSS-REFERENCE TO RELATED APPLICATIONS

This application claims the benefit of priority under 35 U.S.C. § 119 of U.S. Provisional Application No. 63/276,717 filed Nov. 8, 2021, the content of which is incorporated herein by reference in its entirety.

### FIELD OF THE DISCLOSURE

The present disclosure is in the field of etched film surfaces and, more particularly, relates to methods and articles for applying patterns to film surfaces of low melt glass.

### SUMMARY OF THE DISCLOSURE

In some aspects, the disclosure provides for a glass article comprising a glass layer with a transition temperature of less than 450° C. and comprising a thickness and a primary surface. The primary surface defines a plurality of surface features comprising at least one elevated surface protruding relative to at least one relief surface. The elevated surface is defined by an etch mask and the relief surface is defined by an inverse pattern of the etch mask. The relief surface has a depth H relative to the elevated surface from about 0.2 μm to about 10 μm, a width S defined at H/2 and wherein a ratio S/H is in a range from about 1 to about 15.

In some aspects, the disclosure provides for a method of making a glass article. The method comprises depositing an etch mask on a primary surface of a surface layer of a glass substrate. The etch mask forms a pattern on a primary surface. The method further includes exposing the surface layer of the glass substrate to an etchant, thereby removing a relief of the pattern forming a relief surface in the primary surface of the surface layer. The relief has an inverse pattern of the etch mask. The method further incudes removing the etch mask, revealing an elevated surface adjacent to a plurality of troughs formed by the relief surface. The elevated surface and the relief surface form a periodic morphology. The plurality of troughs have a depth H relative to the elevated surface from about 0.2 μm to 10 μm, a width S defined at H/2, and wherein a ratio S/H is in a range from about 1 to about 15.

In another aspect, the disclosure provides for a glass article comprising a film layer deposited on a glass substrate. The film layer has a melting point less than 450° C. and comprises a thickness and a primary surface. The primary surface defines at least one elevated surface protruding relative to the at least one relief surface. The elevated surface forms a periodic pattern defined by an etch mask, and the relief surface is defined as an inverse pattern of the etch mask. The duration of an etching process applied to the film layer defines a ratio of a first area of the elevated surface to a second area of the relief surface.

These and other features, objects and advantages of the present invention will become apparent upon reading the following description thereof together with reference to the accompanying drawings.

### BRIEF DESCRIPTION OF THE DRAWINGS

FIG. 1 is a process diagram of a method for manufacturing a patterned article comprising a film layer of low melt glass;

FIG. 2 is a side view of a patterned glass article comprising a film layer of low melt glass;

FIG. 3A is a side view of a surface feature of a glass article demonstrating an undercutting process;

FIG. 3B is a side view of a surface feature of a glass article demonstrating an undercutting process relative to FIG. 3A;

FIG. 3C is a side view of a surface feature of a glass article demonstrating an undercutting process relative to FIG. 3B;

FIG. 4A is a side view of a patterned article demonstrating a first surface morphology;

FIG. 4B is a side view of a patterned article demonstrating a second surface morphology;

FIG. 5 is a diagram demonstrating a plurality of etch patterns applied to manufacture patterned articles;

FIG. 6 is a diagram demonstrating measured results achieved by applying an etch mask introduced in FIG. 5;

FIG. 7A is an SEM image of a patterned glass article demonstrating a film layer of low melt glass;

FIG. 7B is an SEM image of a patterned glass article demonstrating a film layer of low melt glass;

FIG. 8A is an SEM image of a patterned surface of a film layer demonstrating a sinusoidal morphology;

FIG. 8B is a schematic diagram representing the sinusoidal morphology of FIG. 8A;

FIG. 8C is an SEM image of a patterned surface of a film layer demonstrating a “flat-top” morphology;

FIG. 8D is a schematic diagram representing the flat-top morphology of FIG. 8B;

FIG. 9A is an SEM image of a patterned surface of a film layer processed using a first etch mask;

FIG. 9B is an SEM image of a patterned surface of a film layer processed using a second etch mask;

FIG. 9C is an SEM image of a patterned surface of a film layer processed using a third etch mask;

FIG. 10 demonstrates a plurality of SEM images taken over a period of time demonstrating changing surface features of a flat-top morphology;

FIG. 11 is an exemplary 3D plot of a diffractive optic element demonstrating variations in surface height based on changes in color or shading;

FIG. 12 is an exemplary plot of an optic element including a blue noise diffusive scattering texture;

FIG. 13A is an exemplary schematic diagram of a beam deflector in a first configuration; and

FIG. 13B is an exemplary schematic diagram of a beam deflector in a second configuration.

### DETAILED DESCRIPTION OF THE PREFERRED EMBODIMENT

Additional features and advantages will be set forth in the detailed description which follows and will be apparent to those skilled in the art from the description, or recognized by practicing the embodiments as described in the following description, together with the claims and appended drawings. As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone; A and B in combination; A and C in combination; B and C in combination; or A, B, and C in combination.

In this document, relational terms, such as first and second, top and bottom, and the like, are used solely to distinguish one entity or action from another entity or action, without necessarily requiring or implying any actual such relationship or order between such entities or actions.

Modifications of the disclosure will occur to those skilled in the art and to those who make or use the disclosure. Therefore, it is understood that the embodiments shown in the drawings and described above are merely for illustrative purposes and not intended to limit the scope of the disclosure, which is defined by the following claims, as interpreted according to the principles of patent law, including the doctrine of equivalents.

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. When the term “about” is used in describing a value or an end-point of a range, the disclosure should be understood to include the specific value or end-point referred to. Whether or not a numerical value or end-point of a range in the specification recites “about,” the numerical value or end-point of a range is intended to include two embodiments: one modified by “about,” and one not modified by “about.” It will be further understood that the end-points of each of the ranges are significant both in relation to the other end-point and independently of the other end-point.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, “substantially” is intended to denote that two values are equal or approximately equal. In some embodiments, “substantially” may denote values within about 10% of each other, such as within about 5% of each other, or within about 2% of each other.

Directional terms as used herein—for example, up, down, right, left, front, back, top, and bottom—are made only with reference to the figures as drawn and are not intended to imply absolute orientation.

As used herein the terms “the,” “a,” or “an,” mean “at least one,” and should not be limited to “only one” unless explicitly indicated to the contrary. Thus, for example, reference to “a component” includes embodiments having two or more such components unless the context clearly indicates otherwise.

In general, the disclosure provides for process methods and resulting articles with beneficial optical properties. In various embodiments, the application provides for optical structures formed from glass. More particularly, the articles and structures are formed from glass with a low transition temperature, which may be referred to as low melt glass. The low melt glass may be distinguished from various glass compositions primarily based on the transition temperature being less than 600° C. and may include a phosphate [P₂O₅] glass composition having one or more intermediate oxide additives. In various examples, the melting temperature of the low melt glass may more specifically be less than 500° C., less than 475° C., less than 450° C., and in some examples may be less than 425° C. As discussed in the various examples that follow, the disclosed articles may be formed by one or more patterning techniques to prepare photonic structures, often without requiring the use of harsh acids (e.g., hydrofluoric acid) for etching. Accordingly, the disclosure may provide for improved novel articles and methods of manufacture that may be implemented to improve the performance of optical structures, diffractive optic elements, or similar elements for a variety of applications.

The resulting articles may be favorable to alternative materials (e.g., polymeric materials, conventional glass compositions) because they provide for high temperature operation near emitters, displays, or light sources while limiting the need for harsh chemicals in their manufacture. Additionally, the resulting articles may provide for improved dimensional stability and reliability over polymer alternatives, which makes the optical surface of the resulting articles better suited for optical communications. These qualities of the resulting articles may also be tailored to suit various applications due to the wide range of low melt glass compositions and available non-hazardous etchant solutions (e.g., free of hydrofluoric acid). Examples of etchants may include HCl, H₂SO₄, HNO₃, H₃PO₄, NaH₂PO₄, HBr, etc. Examples of hazardous etchants that may be avoided by practicing this disclosure includes hazardous acids, bases, oxidants, or reducing agents, such as HF, F₂, azides (NaN₃), hydrides (LiAlH), etc. Accordingly, the articles and methods of manufacture supported by the disclosure may provide highly flexible and beneficial properties to suit a variety of applications.

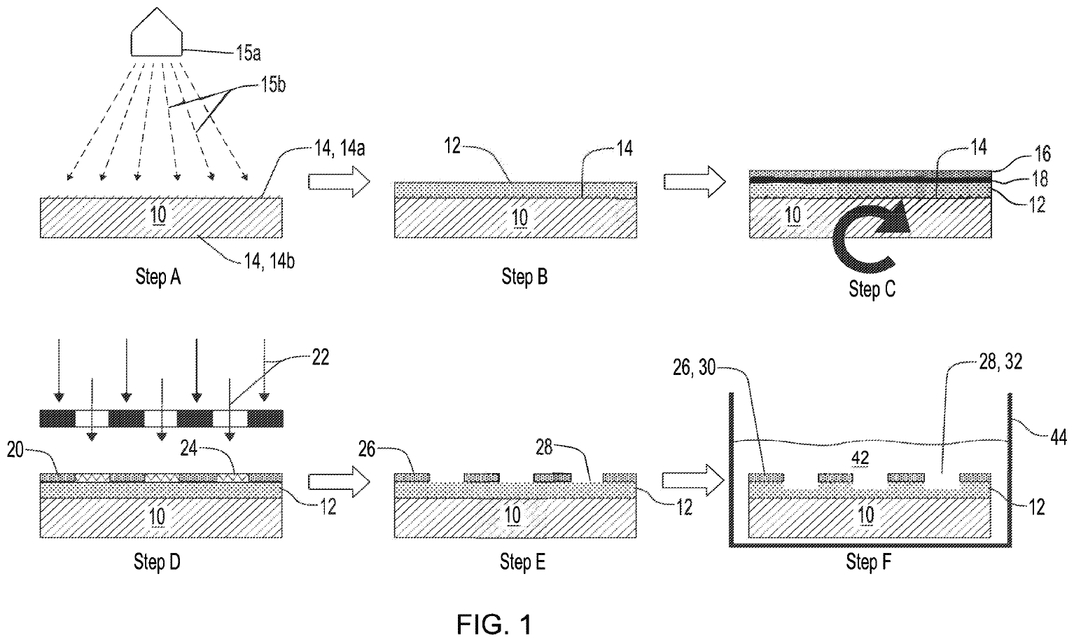

Referring now to FIG. 1, an article as provided by the disclosure may be manufactured via a patterning and etching process as exemplified by the processing steps shown (A-F). The method may begin in step A by preparing and cleaning a substrate 10 and applying a film layer 12 or film of low melt glass over a major surface 14 (e.g., a first major surface 14a, second major surface 14b). The film layer 12 may be applied via a vapor deposition process and may range in thickness depending on the application, but generally may range from approximately ½-5 μm. In some implementations, the thickness may be approximately 1-3 μm or 1½-2 μm. As shown, the film layer 12 may be applied in a vapor deposition process during which the substrate 10 is exposed to material sources 15a, which can produce particles, atoms, molecules, or ions 15b (represented by dashed lines) of a low melt glass material deposited on the major surface 14. Though illustrated as a vapor deposition process in FIG. 1, it is to be understood that any suitable deposition technique can be used to form the film layer 12 on the substrate 10.

In the exemplary procedure described herein, the film layer 12 is applied to the substrate 10 via a deposition process. The resulting film layer 12 is demonstrated in step B. Suitable deposition methods may include non-equilibrium processes, such as ion beam sputtering, magnetron sputtering, and laser ablation. An exemplary apparatus for competing the deposition process of step A may include a vacuum chamber having a substrate stage on which the substrate 10 is positioned. The chamber may be equipped with a vacuum port for controlling the interior pressure, a water cooling port, and a gas inlet port. The vacuum chamber may be cryo-pumped (CTI-8200/Helix; Mass., USA) and may be capable of pressures suitable for both evaporation processes (^{˜}10-6 Torr) and RF sputter deposition processes (^{˜}10-3 Torr). A post-deposition sintering or annealing step of the as-deposited material may be performed or omitted.

In general, suitable materials for forming the film layer 12 may include low melting glasses compositions, such as phosphate glasses, borate glasses, tellurite glasses and chalcogenide glasses. Examples of borate and phosphate glasses include tin phosphates, tin fluorophosphates, and tin fluoroborates. Sputtering targets can include such glass materials or, alternatively, precursors thereof. Examples of copper and tin oxides are CuO and SnO, which can be formed from sputtering targets comprising pressed powders of these materials. Optionally, the composition of the thin film layer 12 can include one or more dopants including, but not limited, to tungsten, cerium and niobium. Such dopants, if included, can affect, for example, the optical properties of the film layer 12 and can be used to control the absorption by the barrier material of electromagnetic radiation, including laser radiation. Examples of tin fluorophosphate glass compositions can be expressed in terms of the respective compositions of SnO, SnF2 and P2O5 in a corresponding ternary phase diagram. Suitable tin fluorophosphates glasses include 20-100 mol % SnO, 0-50 mol % SnF2 and 0-30 mol % P2O5. These tin fluorophosphates glass compositions can optionally include 0-10 mol % WO3, 0-10 mol % CeO2 and/or 0-5 mol % Nb2O5.

For example, a composition of a doped tin fluorophosphate starting material suitable for forming a film layer 12 comprises 35 to 50 mol % SnO, 30 to 40 mol % SnF2, 15 to 25 mol % P2O₅, and 1.5 to 3 mol % of a dopant oxide, such as WO3, CeO2 and/or Nb2O5.

A tin fluorophosphate glass composition according to one particular embodiment is a niobium-doped tin oxide/tin fluorophosphate/phosphorus pentoxide glass comprising about 38.7 mol % SnO, 39.6 mol % SnF2, 19.9 mol % P2O5 and 1.8 mol % Nb2O5. Sputtering targets that can be used to form such a glass layer may include, expressed in terms of atomic mole percent, 23.04% Sn, 15.36% F, 12.16% P, 48.38% O and 1.06% Nb.

A tin phosphate glass composition according to an alternate embodiment comprises about 27% Sn, 13% P and 60% O, which can be derived from a sputtering target comprising, in atomic mole percent, about 27% Sn, 13% P and 60% O. As will be appreciated, the various glass compositions disclosed herein may refer to the composition of the deposited layer or to the composition of the source sputtering target.

As with the tin fluorophosphates glass composition example, tin fluoroborate glass compositions can be expressed in terms of the respective ternary phase diagram compositions of SnO, SnF2 and B2O3. Suitable tin fluoroborate glass compositions include 20-100 mol % SnO, 0-50 mol % SnF2 and 0-30 mol % B2O3. These tin fluoroborate glass compositions can optionally include 0-10 mol % WO3, 0-10 mol % CeO2 and/or 0-5 mol % Nb2O5.

Due to their relatively low melting temperature and chemical liability, process conditions and the resulting layers that include the glass compositions disclosed herein exhibit significant deviation from typical refractory materials. For instance, applicants have shown that the self-passivating character of tin-containing glass compositions can be correlated to the Sn2+(i.e., SnO) content within the formed layer. Data shows that the Sn2+ content is a function of the substrate temperature, and that Sn2+ rich layers can be formed by cooling the substrate during deposition. At higher substrate temperatures, lower amounts of Sn2+ are incorporated into the film layer 12 due to the loss of POxFy and SnFx species at the expense of Sn4+(i.e., SnO2). Thin film layers that incorporate a large fraction of Sn4+ do not readily self-passivate and, therefore, do not form an effective film layer 12.

During formation of the film layer 12, the substrate can be maintained at a temperature less than 200° C., e.g., less than 200° C., 150° C., 100° C., 50° C. or 23° C. In some embodiments, the substrate is cooled to a temperature less than room temperature during deposition of the film layer 12. The target temperature, as well as the substrate temperature, can be controlled in the exemplary sputter deposition processes represented in FIG. 1.

Following the formation of the film layer 12 of the low melt glass composition, the major surface 14 may be coated with a photoresist layer 16 as well as an optional adhesion promoter 18 demonstrated in step C. Each of the photoresist layer 16 and the adhesion promoter 18 may be formed through spin coating, roll coating, or a slit die technique. In cases where a spin coating method is used to form the photoresist layer 16 or apply the adhesion promoter 18, the method may typically be achieved at speeds of 500 rpm or greater. In some cases, spin coating can be performed at multiple speeds, such as a first, slow rotational speed, for example, in a range from about 500 to about 1000 rpm, followed by a second, faster rotational speed, such as in a range from about 2500 rpm to about 3500 rpm. In some cases, the rotational speed may maintain a constant elevated speed in excess of 2000 rpm. In an exemplary embodiment, the photoresist layer 16 may be applied at rates of approximately 3000 rpm.

Following the application of the photoresist layer 16, the substrate 10 may be heated to cure the photoresist layer 16. An example of a photoresist material that may be implemented to achieve the photoresist layer 16 is Micro Resist Technology: Ma-P 1275, which was applied to the film layer via a spin coating process at 3000 rpm, then soft baked or cured at 100° C. for 5 minutes yielding the photoresist layer 16 approximately 6.5 μm in thickness. In general, the photoresist layer 16 may be of a light-sensitive organic material. As shown in step D, a patterned mask 20 may be applied to the photoresist layer 16, such that ultraviolet light from a light source 22 is selectively transmitted through openings 24 in the patterned mask 20, which may correspond to a chromium mask. An exemplary exposure time may be achieve with the light source 22 at approximately 450 mJ/cm² at 365 nm for 140 seconds.

Following the exposure of the photoresist layer 16, a developer solvent is applied to the surface, which reveals the exposed surfaces for further processing as shown in step E. An exemplary developer may include ammonium hydroxide (e.g., CD-26 developer of 0.26N tetra methyl ammonium hydroxide, TMAH). The result of the development is a patterned photoresist layer 16 that may be cured or baked to harden corresponding masked region s 26, which later will form the peaks 30 or elevated regions, while exposed region s 28 will form the channels 32 or relief regions, which may also be referred to as valley s or troughs. The hard curing of the patterned photoresist layer 16 may be achieved at an increased temperature relative to the soft-baking of the photoresist layer 16. In the example provided, the substrate with the film layer 12 and the patterned photoresist layer 16 was hard baked at 120° C. for 5 minutes. In the example provided, a positive photoresist is described. However, the photoresist layer 16 may be a positive or negative photoresist and the applied thickness of the photoresist may vary with the characteristics of the photoresist.

As previously discussed, an adhesion promoter 18 may be implemented to improve the adhesion of the photoresist layer 16 to the film layer 12 of low melt glass. Accordingly, adhesion promoter 18 may be applied to the first major surface 14a of the substrate 10 (e.g., the surface to be etched) prior to application of the etch mask forming the photoresist layer 16. The adhesion promoter 18 can be used to ensure adequate adhesion of the acid resistant material forming the photoresist layer 16. The adhesion promoter 18 can be a silane layer, an epoxysilane layer or a self-assembled siloxane layer. The adhesion promoter 18 can, for example, comprise HardSil™ AM (HAM), an acrylate-based polysilsesquioxane resin solution manufactured by Gelest Incorporated, diluted with 2 methoxy propanol. In some embodiments, the adhesion promoter 18 may be a HAM polysilsesquioxane stock solution diluted to 10% to 50% by volume using 2-methoxy propanol. The HAM solution may be diluted to a polymer concentration of 2% to 10% by volume. Other adhesion promoters suitable for use include octadecyldimethyl (3-trimethoxylsilylpropyl) ammonium chloride in water and/or acetic acid 3-glycidyoxypropyl trimethoxysilane in isopropyl alcohol.

In some embodiments, the adhesion promoter 18 may be applied by painting (rolling). However, in other embodiments, the adhesion promoter 18 may be applied by spin coating or dipping as previously discussed. After application, adhesion promoter 18 can be optionally air dried and cured by baking, for example, at a temperature of about 120° C. to about 300° C. or more specifically in a range from about 150° C. to 200° C., depending on material, for a time in a range from about 5 minutes to 1 hour, for example 20 minutes to about 30 minutes. Once the adhesion promoter 18 is applied and cured, the photoresist layer 16 may be applied as previously discussed.

In step F, the substrate 10 may be etched to form the channels 32 within the film layer 16, thereby forming the patterned article 40 of the disclosure. As shown, the substrate 10, including the film layer 12 and the patterned photoresist layer 16, is exposed to an etchant 42, for example, via a wet etching process in an etching bath 44. The etchant 42 may dissolve or etch unmasked or exposed regions 28 of the film layer 16 forming the patterned structure of the patterned article 40. In the example provided, the pattern of the article 40 is corrugated comprising alternating rows of the channels 32 or relief regions and the peaks 30 or elevated regions. The patterned structure of the patterned article 40 may correspond to an exemplary light guide implementation with various display devices (e.g., displays for consumer electronics). Examples of the etchant 42 may include acids with a pH<1.5 (e.g., phosphoric acid) or acids with a pH<1 (e.g., HCl, H2SO4, all other strong acids). Additionally, the nature of the low melt glass of the film layer 12 may provide for alkaline materials to be applied as the etchant 42. For example, the etchant 42 may comprise an alkaline solution with pH>12.5 (e.g., 1% KOH), which may etch film layers of Corning 870CHM glass. The result of the etching process shown in step F may provide for an etch rate of 0.1 μm/min or greater. Exemplary etch rates and corresponding times for the etching in step F may vary greatly based on the material of the film layer 12 and the pH of the etchant 42. The etch times to process the patterned article 40 were generally greater than 2 minutes and less than 2 hours. Exemplary structures are later demonstrated as the result of increasing etching durations which range from 30 second to 60 minutes and range from 20 minutes to 40 minutes in the examples shown. The resulting structures of the patterned articles 40 are described in various examples demonstrating structures similar to the channels 32 and the peaks 30 previously discussed as well as more complex geometric patterns and topographies.

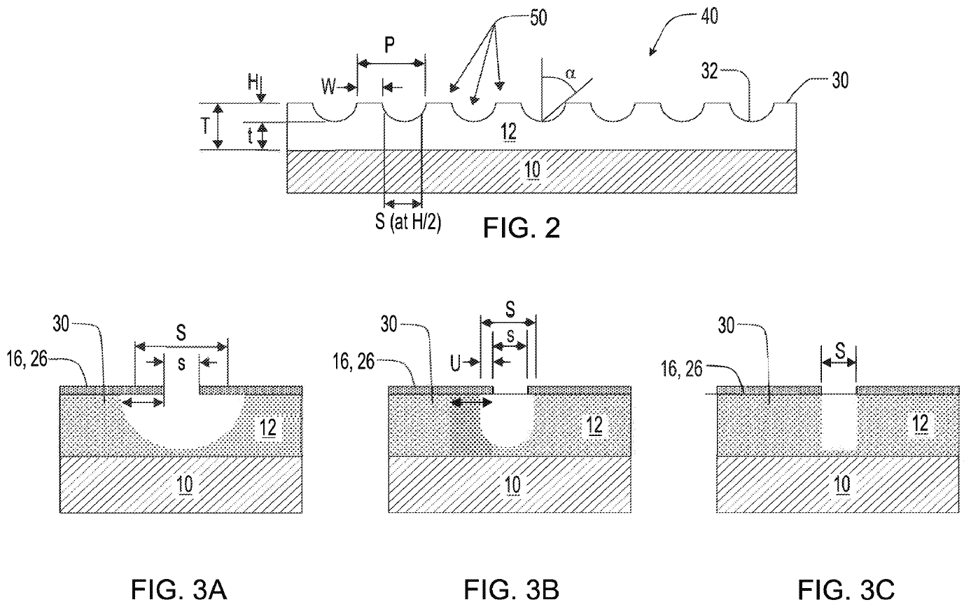

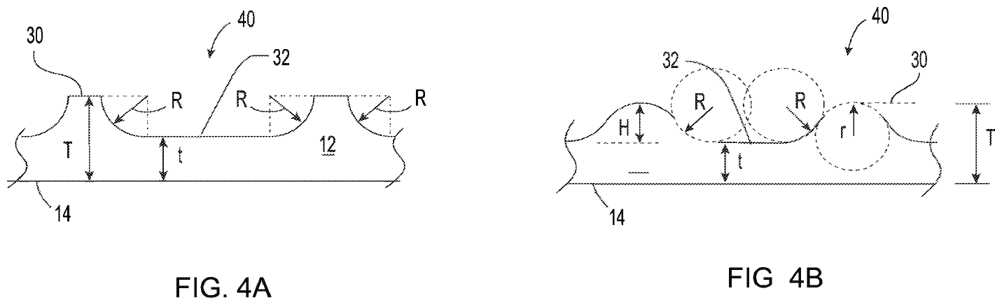

Referring now to FIGS. 2 and 3, exemplary surface features 50 of the patterned article 40 are shown and discussed in further detail in reference to the method of FIG. 1. Referring first to FIG. 2, a side view of the article patterned 40 is shown demonstrating the surface features 50 including the peaks 30 in the form of arcuate peaks, such as circular arcs (e.g., semicircular arcs) separated by the channels 32 or valleys. Each peak 30 may have a width W and each channel may have a width S, which may be defined at H/2. Additionally, each of the peaks 30 may form a wall angle α defined as the angle extending from the point of curvature of the channels 32 to the top of the adjacent peak 30 at height H. In some examples, one or more of the channels 32 may include a depth or height H in a range from about 5 nm to 2000 nm. A corresponding width S of the channels 32 may be defined at H/2. A ratio of S/H of the channels 32 may be in a range of from about 1 to about 15. Accordingly, the dimensions of the surface features 50 that may be achieved for the film layer 12 of low melt glass may be adjusted to form a wide range of geometries and topographies. The wall angles α that may be achieved for the film layer 12 of the low melt glass composition may range from approximately 20°<α<70°. In some cases, the wall angle α may range from 20°<α<40° or 20°<α<30° depending primarily on the implementation of the etch mask forming the photoresist layer 16 and the adhesion promoter 18 as later discussed in greater detail.

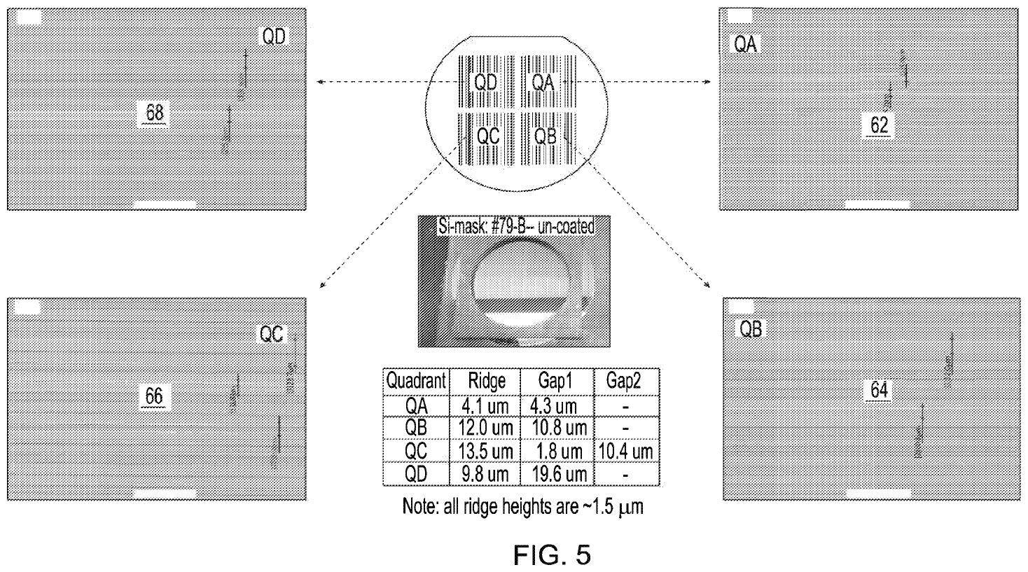

A period P of the peaks 30 and the channels 32 may correspond to the sum of W and S (e.g., P=W+S). The film layer 12 has a full thickness T and a channel thickness t. The channel thickness t is defined as the difference between the channel height H and the full thickness T of the film. As defined, H may be used herein to designate either channel depth or peak height. Accordingly, each of the peaks 30 is defined by the adjacent channels 32 and vice versa. In some cases, a ratio W/H of a peak 30 can vary. The channel depth H and corresponding channel width S of the channels 32 may vary from approximately 5% to 100% of the thickness T of the film layer 12 formed over the substrate 10. As later discussed in reference to FIGS. 4A and 4B, the geometry of the peaks 30 and channels 32 may vary based on a directionality of the etching of the film layer 12 and the extent of the etching, which may be controlled based on the etch rate of the etchant 42 and the time that the substrate 10 is etched as previously discussed in Step F.

Examples of etched profiles are demonstrated in FIGS. 3A, 3B, and 3C to demonstrate directional etching and the resulting surface profiles. FIG. 3A demonstrates an example of an isotopically etched profile with a consistent etch rate in both the vertical and horizontal directions. FIG. 3B demonstrates an example of an anisotropic etched profile with a height vertical etch rate higher than the horizontal etch rate. FIG. 3C demonstrates a directionally etched profile etched in single direction (e.g., vertical). Additional variations in the surface profile of the film layer 12 of the patterned article 40 may be the result of over etching, which may result from etching through the entire thickness of the film layer 12 revealing a portion of the substrate 10 forming a base of the channels 32. The various examples of the patterned article 40 and the corresponding methods of manufacture may be applied to widely vary the characteristics of the surface profiles to suit a variety applications.

In each of the examples of FIGS. 3A and 3B, the channels 32 include an undercut length U, wherein channel width S extends under an opening width s of the mask formed by the photoresist layer 16. Accordingly, an undercut ratio may be defined as U/S and may be varied by varying one or more of the process steps previously discussed in reference to FIG. 1. In particular, the utilization of the adhesion promoter 18 may limit the undercut ratio to 10% or less. In an isotropic process as demonstrated in FIG. 3A, the undercut ratio may be approximately 50%. In an anisotropic process as demonstrated in FIG. 3B, the undercut ratio may be greater than 0% and less than 50%. Finally, in a purely directional etching process as demonstrated in FIG. 3C, the undercut ratio is 0%. Accordingly, the adhesion promoter 18 may be implemented to reduce the undercut ratio.

As previously discussed, the peaks 30 and channels 32 may have a period P and may form repeating surface features 50 over one or more of the major surface 14. In some cases, the peaks 30 and channels 32 or other surface features 50 may not be periodic. The peaks 30 and channels may form a variety of cross-sectional shapes. For example, the channels 32 may form a step shape similar to a rectangular waveform. In some examples, the channels 32 may form arcuate cross-sectional shapes, as shown in FIG. 2, which may resemble a concave circular section, such as a circular arc, with intervening flat topped peaks (e.g., mesas). In such configurations, the surface of the patterned article 40 comprises alternating rows of mesas and arcuate channels. The progression between these example configurations are discussed further in reference to FIGS. 4A and 4B.

Referring now to FIGS. 4A and 4B, embodiments of circular arc channel cross sections are illustrated in FIGS. 4A and 4B. The embodiment of FIG. 4A is similar to the embodiment of FIG. 2 in that FIG. 4A depicts the patterned article 40 comprising the channels 32 with a cross-sectional shape including circular arcs adjacent each of the peaks 30, which are mesa-shaped. The circular arcs define the sidewalls of the peaks 30 and can have a radius of curvature R. The embodiment of FIG. 4B depicts another structured surface comprising arcuate section peaks 30 and channels 32 with arcuate sections. More particularly, the peaks 30 of FIG. 4B form circular arcs with a radius r separated by the channels 32 with circular arcs with a radius R. In certain embodiments, radius r can be less than radius R. Each peak 30 is positioned between circular arcs with radius R, and the side walls of the peaks are defined at least in part by the circular arcs with radius R. In the embodiments of FIGS. 4A and 4B, channel 32 comprises two circular arcs separated by a flat floor. As demonstrated, the height H of each of the peaks 30 is equal to an adjacent channel depth. Accordingly, H may be used herein to designate either channel depth or peak height. Accordingly, each of the peaks 30 is defined by the adjacent channels 32 and vice versa. In some cases, a ratio W/H of a peak 30 can vary. The channel depth H and corresponding channel width S of the channels 32 may vary from approximately 5% to 100% of the thickness T of the film layer 12 formed over the substrate 10.

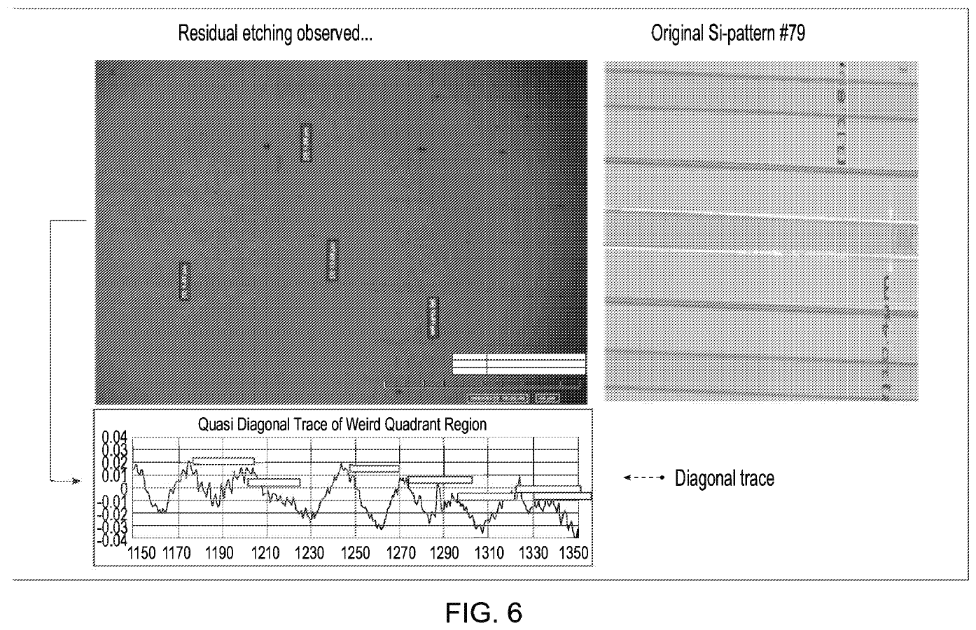

Referring now to FIG. 5 a photolithographic mask 60 was used to assess the resolution of four patterns 62, 64, 66, and 68 in four quadrants QA, QB, QC, and QD distributed on a 6″ chromium mask as depicted. The results demonstrated were produced using the method described in reference to FIG. 1 by wet etching a major surface of a substrate 10 comprising the film layer 12 of low melt glass. The patterns were photolithographically transferred over the film layer 12 to define the four patterns 62, 64, 66, and 68. The geometry and spacing of each of the patterns 62, 64, 66, and 68 are shown in the central table of FIG. 5. As shown, the depth H of each of the channels 32 was approximately 1.5 μm in each of the four quadrants QA, QB, QC, and QD. The pattern 66 in quadrant QC includes the most demanding configuration with a channel 32 with a 1.8 μm width S, the peak 30 with a width W of 13.5 μm, and a 1.5 μm depth H. The first quadrant QA included a width S of the channel 32 of 4.3 μm and a width W of the peak 30 of 4.1 μm. The second quadrant QB included a width S of the channel 32 of 10.8 μm and a width W of the peak 30 of 12.0 μm. The fourth quadrant QD included a width S of the channel 32 of 19.6 μm and a width W of the peak 30 of 9.8 μm.

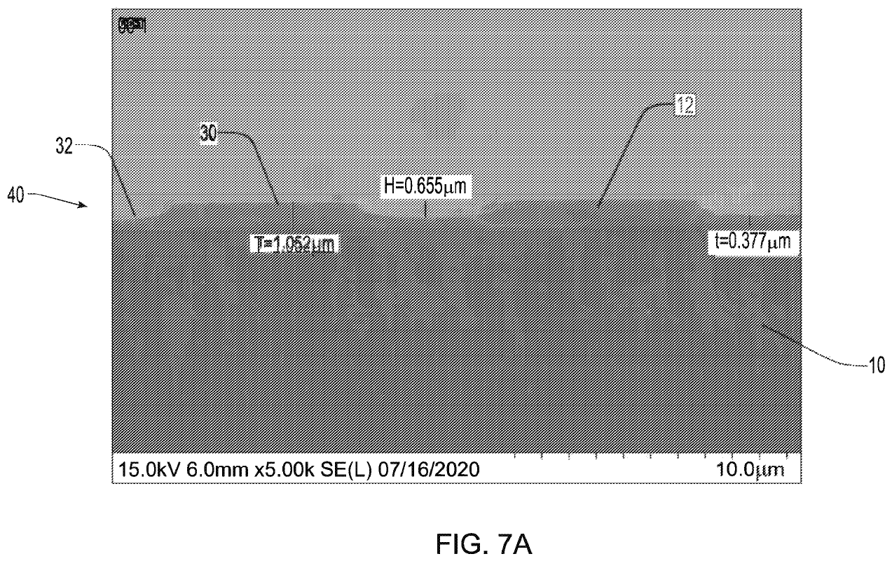

Referring now to FIG. 6, results from wet etching a major surface 14 of a substrate 10 comprising the film layer 12 of 1.5 μm of low melt glass are shown and discussed in further detail. The pattern applied in the sample result shown was produced with the pattern 66 in quadrant QC. The resulting patterned article 40 was prepared using the method described in FIG. 1. More specifically, the major surface 14 was patterned with a simple photoresist (Micro Resist Technology: Ma-P 1275) and spin coated at 3000 RPM yielding 6.5 μm thick photoresist layer 16. The photoresist layer 16 was soft-baked at 100° C. for 5 minutes and exposed to the light source 22 for 450 mJ/cm² at 365 nm. After exposure, the film layer 12 was developed for 140 seconds with CD-26 developer (0.26N tetramethyl ammonium hydroxide, TMAH) and then hard bake at 120° C. for 5 minutes. Next the substrate 10 with the patterned photoresist layer 16 was wet etched with an etchant 42 of 6 M HCl for 5 minutes.

As shown in FIG. 6, the patterned article 40 was measured to have a central gap or channel 32 with a width S=1.81 μm and a neighboring peak 30 with a width W=13.08 μm. These measured results shown in the left image were identified to correlate well with the known attributes associated with the pattern 66 in quadrant QC, previously noted to include a channel 32 with a width S=1.8 μm and a neighboring peak 30 with a width W=13.5 μm. The spatial correlation is visually apparent when comparing the reference image (right) with the captured image (left), which indicates that the method applied is capable of producing high resolution surface features 50. The bottom of FIG. 6 illustrates a profilometer scan captured with a KLA Tencor-AlphaStep D-600 profilometer. The scan was captured along a diagonal, relative to the top right image, to account for a relatively large profilometer stylus tip radius (2 μm) and ensure the gaps were well characterized in a low signal-to-noise measurement. While the 2D spatial dimensions matched well with the original pattern 66 of the QC quadrant, the 20-40 nm feature heights indicated that the etchant 42 may undercut the photoresist layer 16. In various experiments chromium Cr masks may be applied to achieve 2000 nm etch depths.

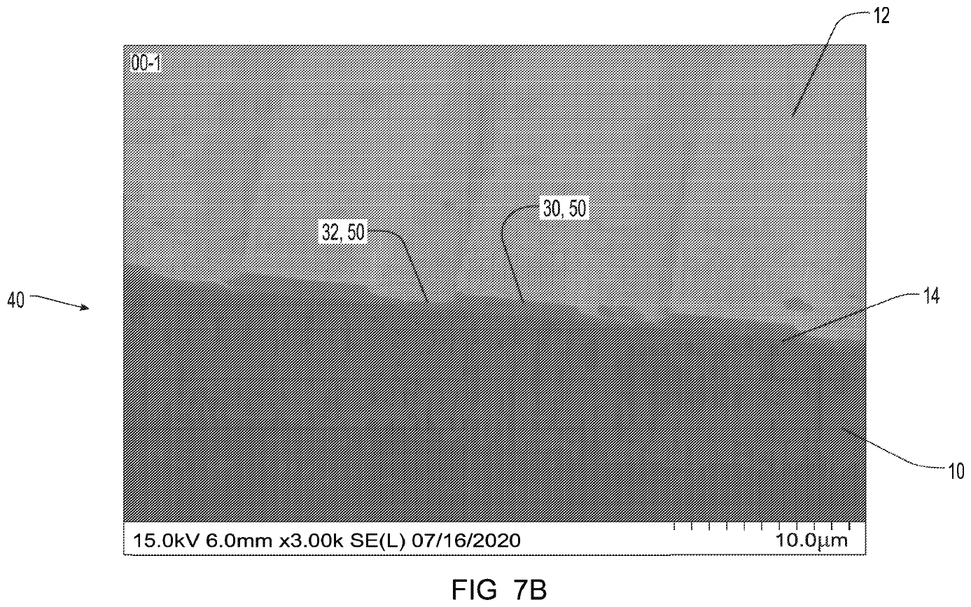

Referring now to FIGS. 7A and 7B, scanning electron microscope (SEM) images are shown depicting an exemplary patterned article 40 manufactured using the method described in reference to FIG. 1. The images demonstrate exemplary surface features 50 etched into the major surface 14. More specifically, the process implemented to manufacture the film layer 12 of low melt glass included etching the film layer 12 with a 1% KOH etchant 42 through a patterned chromium mask for 1 minute. The mask pattern implemented was the QD pattern 66 which was applied to the film layer having a thickness T=1 μm. As previously discussed, the resulting geometry of the patterned article 40 may result in the exposed regions 28 forming the channels 32 or relief regions and the masked regions 26 forming the peaks 30 or elevated regions. The exemplary surface features 50 include a film layer 12 with a full thickness T=1.052 μm, a channel thickness t=0.377 μm, and a channel height H=0.655 μm. Accordingly, the height H is approximately equivalent to the difference between the full thickness T of the film layer 12 and the channel thickness t across multiple neighboring channels 32 and peaks 30.

In some implementations, the film layer 12 of the substrate 10 may be prepared with a specific etchant that interacts with the low melt glass composition of the film layer to yield trace surface chemistry. The surface chemistry may be identifiable with X-ray fluorescence (XRF), Microbe, or dynamic SIMS techniques. In practice, the etched surface chemistry of the patterned article 40 may serve as an identifier of the interaction between the film layer 12 and the etchant 42. For example, the surface chemistry of the film layer 12 with a low melt glass composition may be characterized based on XRF results characterizing the etching procedure used to etch the film layer. For example, the low melt glass composition of the film layer 12 may be measured on un-etched and etched substrates to compare the elemental concentration. Based on the comparison, the film layer 12 may experience preferential leaching, contamination, and/or roughening. From this experimentation, it has been determined that that the solubility and microstructure of the silica-rich leached layers of film layers are similar to the film layer 12. Accordingly, the microstructure of the film layer 12 may vary sample to sample, with some leaching and/or incongruent dissolution occurring, to include varying degrees of ion-exchange. Such variations in microstructure may even be found within the same alum inosilicate glass family. For example, X-ray photoelectron spectroscopic (XPS) data has revealed significant depletion in both sodium and aluminum.

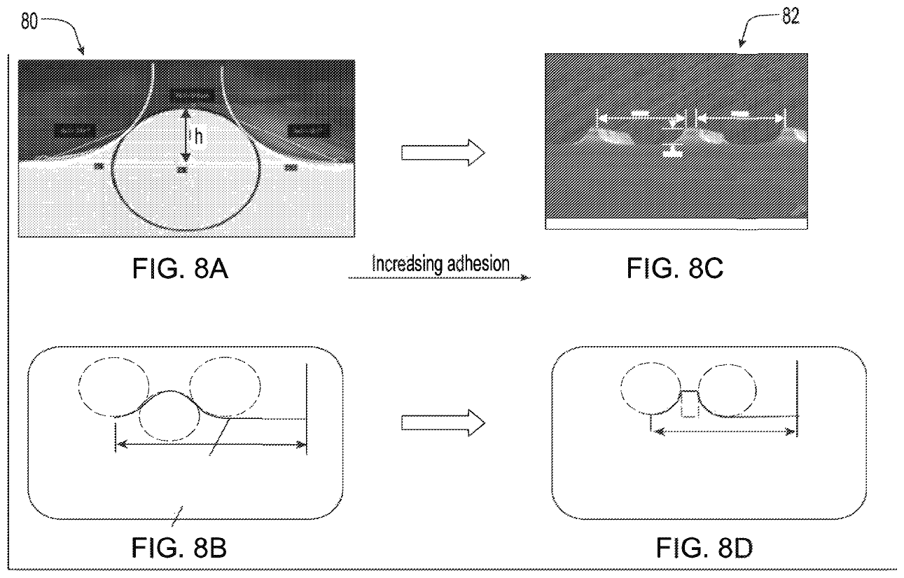

Referring now to FIGS. 8-10, the topography of the surface features 50 of the patterned article 40 may be tuned by adjusting various factors associated with the etching of the low melt glass composition of the film layer 12. Referring first to FIGS. 8A, 8B, 8C, and 8D, exemplary surface features 50 are demonstrated that may be achieved by adjusting the adhesion promoter 18. The examples shown in FIGS. 8A-D are in relation to lenticular light guide plates (LGP). The resulting topographies depend strongly on the degree of adhesion of the etch mask forming the photoresist layer 16 to the film layer 12. In some cases, interfacial surface-adsorbed (physisorbed) water may significantly influence the degree of adhesion during etching steps, similar to those discussed in Step F. While the etchant 42 chosen to etch the film layer 12 also plays a role in the resulting surface features 50, the magnitude of “under-cutting” may be strongly dependent on residual physisorbed interfacial moisture. Examples of etch resistant inks include multi component systems containing an organic polymer, dispersants, emulsifiers, crosslinking agents, pigment, antioxidants, solvents, adhesion promoters, and an inorganic material. Typical polymers were principally acrylate resins, epoxy resins, phenolic resins, and polysiloxanes.

As demonstrated by comparing FIGS. 8A, 8B to FIGS. 8C, 8D; the surface features 50 of the film layer 12 may range from sinusoidal morphologies 80 (8A, 8B) to varying degrees of “flat-top” morphologies 82 (8A, 8B), by varying etch-mask adhesion to the substrate for spray etching. The sinusoidal morphology 80 (e.g., concave-convex-concave morphology) includes characteristics similar to those previously discuss in FIG. 4B, while the “flat-top” morphology 82 (e.g., concave-rectangle-concave) includes characteristics similar to those previously discuss in FIG. 4A. The sinusoidal morphology 80 may be achieved by applying the etch mask forming the photoresist layer 16 directly to the film layer 12 without an intervening adhesion promoter 18. The resulting sinusoidal morphology 80 may be caused by significant undercutting U under the photoresist layer 16. In the example diagram shown in FIG. 8B, the surface features 50 may include a period P with a minimum repeating unit 150 μm and a height of approximately 55 μm. In the example diagram shown in FIG. 8D, the surface features 50 may include a similar period P and resulting height H; however, the topography of the features 50, particularly the radius r of the peaks 30 may drastically change as depicted by increasing the effectiveness of the adhesion promoter 18. Accordingly, the topography of the features 50 (e.g., ratio W/H, undercut ratio U/S, etc.) may be adjusted by varying degrees of adhesion of the etch mask. Exemplary patterned articles 40 that may correspond to those shown in FIGS. 8A and 8C may be etched with similar photolithographic patterns 62, 64, 66, and 68 as previously discussed in reference to FIG. 5.

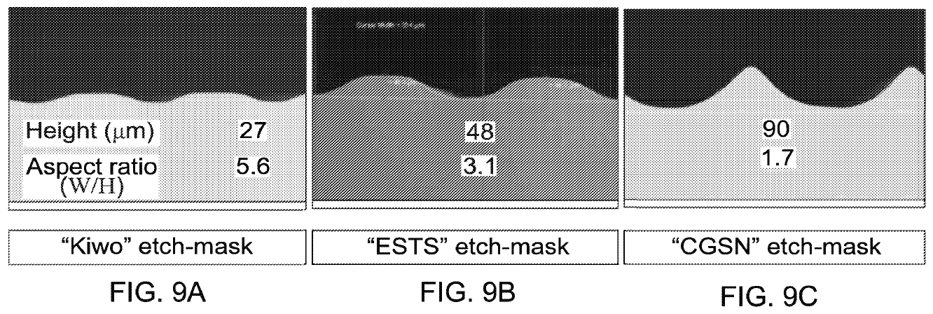

Referring now to FIGS. 9A, 9B, and 9C; the topography of the surface features 50 may also be varied by adjusting the etching procedure as previously discussed in Step F. For example, in cases where the etching is processed by bath etching, the topography may be limited to variation within a range of the sinusoidal morphology 80. Put differently, the “flat-top” morphology 82 may altered by rapidly introducing the radius to the peaks 30. As shown in FIGS. 9A-C, three samples were subjected to the three screen etch-masks (“Kiwo”, “ESTS”, “CGSN”). The formulation of each of the screen etch-masks included differing amounts of adhesion promoter with the Kiwo, ESTS, and CGSN forming a series from weak to strong. Each of the resulting patterned articles 40 were processed with steps similar to those previously discussed in reference to FIG. 1. FIGS. 9A, 9B, and 9C demonstrate an exemplary range of heights H and ratios (e.g., ratio W/H, undercut ratio U/S, etc.) that may be achievable for the film layer 12 in the range of “sinusoidal” morphologies 80. By adjusting these morphologies, the patterned articles 40 produced may have varying optical parameters influencing optical performance, such as the light confinement index (LDI).

Accordingly, based on the etching process applied, the sinusoidal morphologies 80, as originally introduced in FIG. 4A, may be varied to suit a variety of applications. For example, the concave radius R of the channels 32 may range from approximately 5 μm to 10 cm with a curvature of ⅕ μm to 1/100 μm. The convex circular radius r of the peaks 30 may similarly range from 5 μm to 10 cm with a height H from approximately 5 μm to 100 μm. The period P of the minimum period unit (e.g., series of repeating features 50) may vary from a corresponding distance of the widths from approximately 5 μm to 10 cm.

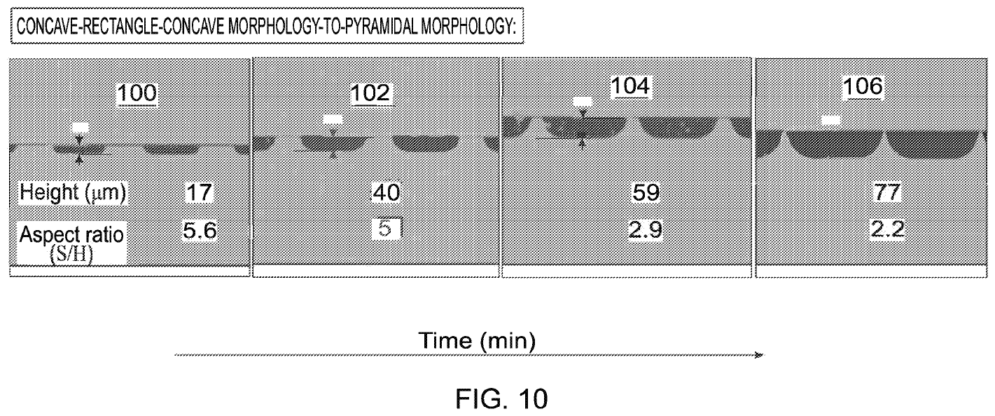

Referring now to FIG. 10, the topography of the surface features 50 may additionally be adjusted by adjusting an immersion duration during a spray etching process. As shown, the surface features 50 of articles 100, 102, 104, and 106 may be controlled by varying a duration of a spray etching process. The spray etching process may differ from an immersion process in that the substrate 10 may be sprayed with the etchant 42 rather than submerged in the bath 44. In the example shown, each of the articles 100, 102, 104, and 106 were submerged for increasing durations of time. Depending on the specific etchant 42 and composition of the film layer 12, the times may vary drastically. In most cases, the range of surface features 50 demonstrated in FIG. 10 may be achieved over a time of less than 60 minutes. The durations corresponding to the depicted samples shown were spray etched for durations of 20, 30, 35, and 40 minutes, respectively. While these times may not be representative of the total time necessary to form the resulting patterned articles 40, the rate of change of the morphologies may similarly occur with various low melt glass compositions. As shown, the topography of the peaks 30 may be adjustable, spanning a range from “flat-top” morphologies 100, 102 to “pyramidal” morphologies 104, 106 by varying a duration of the etch mask duration in a spray etcher. As shown, the aspect ratio S/H gradually decreases as the width S of the channels 32 increases at a decreasing rate relative to the increase in the height H.

Accordingly, based on the etching process applied, the flat-top morphologies 82, as originally introduced in FIG. 4B, may also be varied to suit a variety of applications. For example, the concave radius R of the channels 32 may range from approximately 5 μm to 1 cm with a curvature of ⅕ μm to 1/1 cm. The width W of the peaks 30 may range from approximately 5 μm to 10 cm with a height H from approximately 5 μm to 100 μm. The period P of the minimum period unit (e.g., series of repeating features 50) m ay vary from a corresponding distance of the widths from approximately 50 μm to 10 cm.

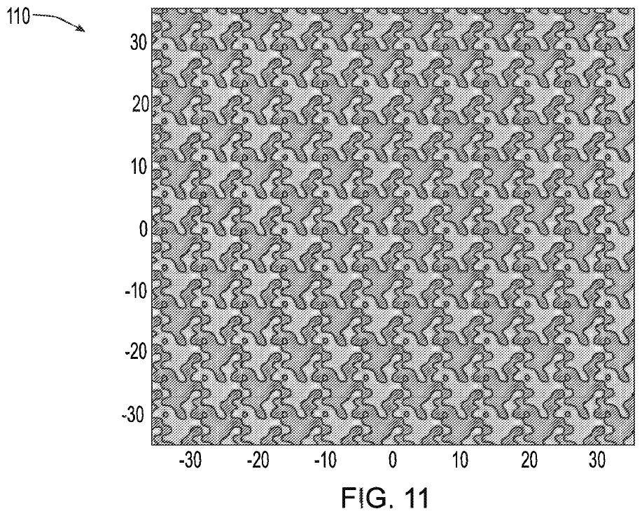

Referring next to FIGS. 11-13, additional examples of patterned articles 40 are shown demonstrating diffractive optic elements 110, 115, 120, and 122. As demonstrated in FIG. 11, the surface features 50 result in a surface texture that consists of two surface levels (etched and non-etched). The units of the surface features of the plot shown in FIG. 11 are μm. The relative depth of the levels may depend on the wavelength of the incident light and whether the patterned article 40 is intended for transmission or reflection. The optic element 110 is an exemplary 6×6 beam splitter with pincushion distortion correction at 633 nm wavelength. The light and dark blue regions indicate a first surface height and the yellow-green areas indicate a second height. A ratio and relative height of the first height and the second height is adjusted depending on the wavelength of the incident light and whether the optic element 110 is meant to be used in transmission or reflection.

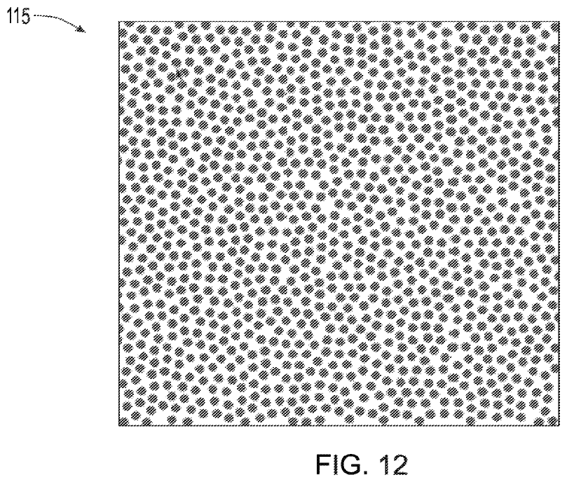

Referring now to FIG. 12, an optic element 115 may include a blue noise diffusive scattering texture for advanced display backlight local dimming. The structure is called a blue noise dimming device because its power spectral density has very little power at low frequencies. This means that specular transmission (or reflection, depending on the application) may be rejected in favor of scattering at larger angles. As shown, the surface texture formed by the features 50 may consist of two surface levels including an etched or relief surface and a non-etched or elevated surface. A fill fraction of each of the surfaces corresponding to the first height and the second height of the surface levels may be 50% for complete specular rejection. The fill fraction may generally control the diameters or relative proportions of the surface features 50. The non-etched surfaces may correspond to the peaks 30 and the etched surfaces may correspond to the channels 32 in terms analogous to the configurations previously described. The relative depth of the etched surfaces may be adjusted to control whether the optical element 115 transmits or reflects a wavelength or range of wavelengths of incident light. The spacing of the features 50 may also be adjusted based on the photolithographic pattern to adjust the performance of the optic element 115 in relation to different wavelengths to produce a maximum scattering angle as desired.

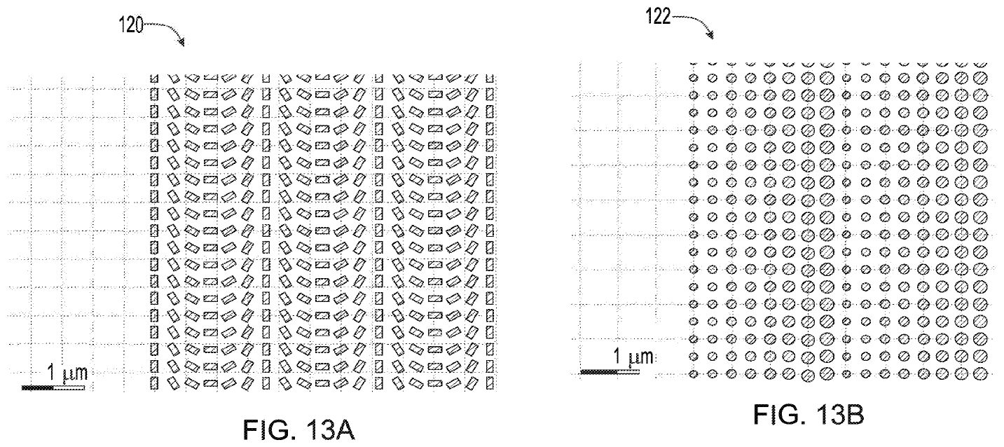

Referring to FIGS. 13A and 13B, the patterned article 40 may provide for various beam deflectors 120, 122. The beam deflector 120 may correspond to a Pancharatnam-Berry phase metasurface beam deflector. In the example shown, the beam deflector 120 may include a deflection angle of 18° and may be designed for 633 nm incident wavelengths. The beam deflector 122 may correspond to a transmit-array metasurface beam deflector. The beam deflector 122 may also include a deflection angle of 18° and may be designed for 633 nm incident wavelengths. Each of the beam deflectors 120, 122 or similar devices may be manufactured with processes similar to those discussed in reference to FIG. 1 with the film layer 12 of low melt glass. The beam deflectors 120, 122 may include surfaces textures or features 50 implemented to form a passive dielectric optical metasurface for applications such as flat optics, chiroptical spectrometers, or high efficiency beam splitters. The surface features 50 may consist of two surface levels (etched and non-etched) with relative depths that may be adjusted depending on the wavelength of the incident light and whether the glass article is meant to be used in transmission or reflection. The spacing of the features and feature sizes may also be determined based on the wavelength and the maximum scattering angle desired, but is mainly sub-wavelength. The metasurface pattern forming the features 50 may be adjusted based on transmit-array structures or Pancharatnam-Berry phase structures, depending on the application. In some examples, the patterned article 40 comprising the film layer 12 of low melt glass may also be implemented on a piezoelectric article to form an active dielectric metasurface structure for applications such as beam steering. In one embodiment, an applied voltage to the surface can be tuned so that the spacing between the dielectric elements is modified, thus changing the output diffracted angle.

According to a first aspect, a glass article comprises a glass layer with a transition temperature of less than 450° C., a thickness, and a primary surface. The primary surface defines a plurality of surface features comprising at least one elevated surface protruding relative to at least one relief surface. The elevated surface is defined by an etch mask, and the relief surface is defined by an inverse pattern of the etch mask. The relief surface has a depth H relative to the elevated surface from about 0.2 μm to about 10 μm, a width S defined at H/2 and wherein a ratio S/H is in a range from about 1 to about 15.

According to a second aspect, the glass layer comprises a phosphate [P₂O₅] composition, in mole percent, between 15%≤[P₂O₅] mol %≤35%, and self-passivating intermediate oxide additives [SPIO], in mol % ranging from 20%≤[SPIO] mol %≤85%.

According to a third aspect, the glass layer contains a self-passivating intermediate oxide additive [SPIO], in mol % ranging from 20%≤[SPIO] mol %≤85%, consisting of one or more elements Sn, Ti, V, Bi, Mo, W, S, Se, Te, Al, Nb, Cu.

According to a fourth aspect, the surface features form a wall angle of a wall extending from a base portion of the relief surface to an adjacent peak of the elevated surface.

According to a fifth aspect, the wall angle is between 20° and 70°, between 20° and 40°, or between 10° and 30°.

According to a sixth aspect, the etch mask forms a pattern comprising a series of the elevated surfaces and a series of troughs forming the relief surface therebetween.

According to a seventh aspect, the glass article is a diffractive optical beam splitting element configured to transmit light therethrough.

According to an eighth aspect, the pattern forms a surface texture and the depth H ranges from 0.2 μm-10 μm.

According to a ninth aspect, a method of making a glass article comprises depositing an etch mask on a primary surface of a surface layer of a glass substrate. The etch mask forms a pattern on the primary surface. The surface layer is exposed the surface layer of the glass substrate to an etchant, thereby removing a relief of the pattern forming a relief surface in the primary surface of the surface layer glass substrate. The relief surface has an inverse pattern of the etch mask. Removing the etch mask reveals an elevated surface adjacent to a plurality of troughs, wherein the elevated surface and the relief surface form a periodic morphology. The plurality of troughs have a depth H relative to the elevated surface from about 0.2 μm-10 μm, a width S defined at H/2, and wherein a ratio S/H is in a range from about 1 to about 15.

According to a tenth aspect, the surface layer has a melting temperature of less than 450° C.

According to a eleventh aspect, the relief surface is etched at a rate of greater than 0.1 μm/min.

According to a twelfth aspect, the etchant is from a family of chemicals comprising: Acid pH<1.5 (phosphoric acid), pH<1 (HCl, H₂SO₄, all other strong acids); or Alkaline. pH>12.5, e.g. 1% KOH (pH-13.4) etches Corning 870CHM sputtered film ˜ 0.5 μm/1 min.

According to a thirteenth aspect, the etch mask comprises an adhesion promoter configured to bond the etch mask to the primary surface.

According to a fourteenth aspect, the ratio S/H of the periodic morphology is adjusted based on variation in the concentration of adhesion promotor coupling the LMG metal oxide and etch mask.

According to a fifteenth aspect, a first surface area formed by elevated surface is adjusted in response to a duration of the exposure of the surface layer of the glass substrate to the etchant.

According to a sixteenth aspect, a second surface area of the relief surface formed by the troughs is adjusted inversely proportional to the first surface area in response to the duration of the exposure to the etchant.

According to a seventeenth aspect, a glass article comprises a film layer deposited on a glass substrate. The film layer comprises a melting point less than 450° C., a thickness, and a primary surface. The primary surface defines at least one elevated surface protruding relative to at least one relief surface, where the elevated surface forms a periodic pattern defined by an etch mask and the relief surface is defined as an inverse pattern of the etch mask. The duration of an etching process applied to the film layer defines a ratio of a first area of the elevated surface to a second area of the relief surface.

According to an eighteenth aspect, the etching process comprises an etching rate of at least 0.1 μm/min.

According to a nineteenth aspect, the relief surface exhibits an increase of at least 1% of Sn (e.g., an SPIO metal) or PO₄ relative to the bulk composition in response to the etching process.

According to a twentieth aspect, an etchant of the etching process is free of HF.

According to a twenty-first aspect, the duration of the etching process causes a morphology of the elevated surface to range from a plateau-shaped cross section to a pointed cross section.

According to a twenty-second aspect, the elevated surface forms a flat top of the plateau-shaped cross section and a peak of the pointed cross section.

According to a twenty-third aspect, the etch mask comprises an adhesion promoter configured to bond the etch mask to the primary surface.

According to a twenty-fourth aspect, the undercut ratio U/S, due to the use of the adhesion promotor, is less than 10%, resulting in the elevated surface forming a flat surface profile.

According to a twenty-fifth aspect, the undercut ratio U/S, due to the use of the adhesion promotor, is greater than 50% results in the elevated surface forming a rounded surface profile if the lateral etch length is 50% or greater than the pattern pitch P.

According to a twenty-sixth aspect, the glass substrate is from a group comprising the preferred embodiment phosphate glass compositions: tin fluoro-phosphate range: 20-85% Sn, 2-20% P, 3-20% O, 10-36% F, and at least 75%=Sn+P+O+F, with one of more elements from {Sn, Ti, V, Bi, Mo, W, S, Se, Te, Al, Nb, Cu}.

According to a twenty-seventh aspect, the glass substrate is more specifically from a group comprising: Corning 870CHM: 40 mol % SnO, 38 mol % SnF₂, 20 mol % P₂O₅, 2 mol % Nb₂O₅; Corning 891 ILH. 35 mol % SnO, 45 mol % % SnF₂, 15 mol % P₂O₅, 2 mol % WO_{3; OR} Tin boro-phosphate: 23.3 mol % P₂O₅, 67.0 mol % SnO, 10.0 mol % B₂O₃.

It is also to be understood that variations and modifications can be made on the aforementioned structures and methods without departing from the concepts of the present device, and further it is to be understood that such concepts are intended to be covered by the following claims unless these claims by their language expressly state otherwise.

The above description is considered that of the illustrated embodiments only. Modifications of the device will occur to those skilled in the art and to those who make or use the device. Therefore, it is understood that the embodiments shown in the drawings and described above are merely for illustrative purposes and not intended to limit the scope of the device, which is defined by the following claims as interpreted according to the principles of patent law, including the Doctrine of Equivalents.

1. A glass article, comprising:
a glass layer with a transition temperature less than 450° C. comprising a thickness and a primary surface,
wherein the primary surface defines a plurality of surface features comprising at least one elevated surface protruding relative to at least one relief surface,
wherein the elevated surface is defined by an etch mask and the relief surface is defined as an inverse pattern of the etch mask, and
wherein the at least one relief surface has a depth H relative to the elevated surface from about 0.2 μm to about 10 μm, a width S defined at H/2, and wherein a ratio S/H is in a range from about 1 to about 15.

2. The glass article in accordance with claim 1, wherein the glass layer comprises a phosphate [P₂O₅] composition, in mole percent, between 15%≤[P₂O₅] mol %≤35%, and self-passivating intermediate oxide additives [SPIO], in mol % ranging from 20%≤[SPIO] mol %≤85%.

3. The glass article in accordance with claim 2, wherein the glass layer contains a self-passivating intermediate oxide additive [SPIO], in mol % ranging from 20%≤[SPIO] mol %≤85%, consisting of one or more elements Sn, Ti, V, Bi, Mo, W, S, Se, Te, Al, Nb, Cu.

4. The glass article according to claim 3, wherein the surface features form a wall angle of a wall extending from a base portion of the relief surface to an adjacent peak of the elevated surface.

5. The glass article according to claim 2, wherein the wall angle is between 20° and 70°, between 20° and 40°, or between 10° and 30°.

6. The glass article according to claim 3, wherein the etch mask forms a pattern comprising a series of the elevated surfaces and a series of troughs forming the relief surface therebetween.

7. The glass article according to claim 6, wherein the glass article is a diffractive optical beam splitting element configured to transmit light therethrough.

8. The glass article according to claim 6, wherein the pattern forms a surface texture and the depth H ranges from 0.2 μm-10 μm.

9. A method of making a glass article, comprising
depositing an etch mask on a primary surface of a surface layer of a glass substrate, the etch mask forming a pattern on the primary surface;
exposing the surface layer of the glass substrate to an etchant, thereby removing a relief of the pattern forming a relief surface in the primary surface of the surface layer glass substrate, the relief surface having an inverse pattern of the etch mask; and
removing the etch mask revealing an elevated surface adjacent to a plurality of troughs, wherein the elevated surface and the relief surface form a periodic morphology, wherein the plurality of troughs have a depth H relative to the elevated surface from about 0.2 μm-10 μm, a width S defined at H/2, and wherein a ratio S/H is in a range from about 1 to about 15.

10. The method according to claim 9, wherein the surface layer has a melting temperature of less than 450° C.

11. The method according to claim 9 wherein the relief surface is etched at a rate of greater than 0.1 μm/min.

12. The method according to claim 9, wherein the etchant is from a family of chemicals comprising:
Acid: pH<1.5 (phosphoric acid); pH<1 (HCl, H₂SO₄, all other strong acids); or
Alkaline: pH>12.5, e.g. 1% KOH (pH-13.4) etches Corning 870CHM sputtered film ˜0.5 μm/1 min.

13. The method according to claim 9, wherein the etch mask comprises an adhesion promoter configured to bond the etch mask to the primary surface.

14. The method according to claim 9, wherein the ratio S/H of the periodic morphology is adjusted based on variation in the concentration of adhesion promotor coupling the LMG metal oxide and etch mask.

15. The method according to claim 9, wherein a first surface area formed by elevated surface is adjusted in response to a duration of the exposure of the surface layer of the glass substrate to the etchant.

16. The method according to claim 15, wherein a second surface area of the relief surface formed by the troughs is adjusted inversely proportional to the first surface area in response to the duration of the exposure to the etchant.

17. A glass article, comprising:
a film layer deposited on a glass substrate, the film layer comprising a melting point less than 450° C. comprising a thickness and a primary surface,
wherein the primary surface defines at least one elevated surface protruding relative to at least one relief surface,
where the elevated surface forms a periodic pattern defined by an etch mask and the relief surface is defined as an inverse pattern of the etch mask, and
wherein the duration of an etching process applied to the film layer defines a ratio of a first area of the elevated surface to a second area of the relief surface.

18. The glass article according to claim 17, wherein the etching process comprises an etching rate of at least 0.1 μm/min.

19. The glass article according to claim 17, wherein the relief surface exhibits an increase of at least 1% of Sn (e.g., an SPIO metal) or PO₄ relative to the bulk composition in response to the etching process.

20. The glass article according to claim 17, wherein an etchant of the etching process is free of HF.

21. The glass article according to claim 17, wherein the duration of the etching process causes a morphology of the elevated surface to range from a plateau-shaped cross section to a pointed cross section.

22. The glass article according to claim 21, wherein the elevated surface forms a flat top of the plateau-shaped cross section and a peak of the pointed cross section.

23. The glass article according to claim 17, wherein the etch mask comprises an adhesion promoter configured to bond the etch mask to the primary surface.

24. The glass article according to claim 23, wherein the undercut ratio U/S, due to the use of the adhesion promotor, is less than 10%, resulting in the elevated surface forming a flat surface profile.

25. The glass article according to claim 24, wherein the undercut ratio U/S, due to the use of the adhesion promotor, is greater than 50% resulting in the elevated surface forming a rounded surface profile if the lateral etch length is 50% or greater than the pattern pitch P.

26. The glass article according to claim 17, wherein the film layer is from a group comprising:
Preferred embodiment phosphate glass compositions: tin fluoro-phosphate range: 20-85% Sn, 2-20% P, 3-20% O, 10-36% F, and at least 75%=Sn+P+O+F, with one of more elements from {Sn, Ti, V, Bi, Mo, W, S, Se, Te, Al, Nb, Cu}.

27. The glass article according to claim 26, wherein the film layer is more specifically from a group comprising:
Corning 870CHM: 40 mol % SnO, 38 mol % SnF₂, 20 mol % P₂O₅, 2 mol % Nb₂O₅;
Corning 891ILH: 35 mol % SnO, 45 mol % % SnF₂, 15 mol % P₂O₅, 2 mol % WO₃; or
Tin boro-phosphate: 23.3 mol % P₂O₅, 67.0 mol % SnO, 10.0 mol % B₂O₃.
